(19) United States
(12) Patent Application Publication
(10) Pub. No.: US 2006/0258080 A1
(43) Pub. Date: Nov. 16, 2006

(54) Vertical diode, matrix position sensitive apparatus and manufacturing method of the same

(75) Inventor: Mitsuasa Takahashi, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC LCD TECHNOLOGIES, LTD., Kawasaki (JP)

(21) Appl. No.: 11/430,896

(22) Filed: May 10, 2006

(30) Foreign Application Priority Data
May 11, 2005 (JP) 138359/2005

(51) Int. Cl. H01L 21/8238; H01L 23/58

(52) U.S. Cl. 438/231; 257/594

(57) ABSTRACT

A vertical diode formed by stacking semiconductor layers includes (1) a lower electrode whose surface is plasma-treated in a gas containing an element which becomes a P-type or N-type conductivity type, and (2) a non-doped semiconductor layer provided on the lower electrode. The P-type or N-type semiconductor area is formed in a contact surface of the non-doped semiconductor layer in contact with the plasma-treated surface of the lower electrode.

### BACKGROUND OF THE INVENTION

1. Field of the Invention

The present invention relates to a vertical diode and a matrix position sensitive apparatus and a manufacturing method of the same, and more particularly to the vertical diode, the matrix position sensitive apparatus, which can be easily manufactured, and the manufacturing method of the same.

2. Description of the Related Art

In recent years, a product referred to as tablet personal computer (tablet PC) has been developed and sold. The conventional tablet PC is constituted such that a tablet capable of sensing pressure and effecting position input, is stacked on the surface of a liquid crystal display as a display region. In the tablet for inputting position, two sheets of transparent substrates, each having a transparent electrode formed thereon, are arranged so that the transparent substrates face each other with a space between the transparent substrates. With this constitution, when a pressure is applied to the transparent substrate by a pen and the like, the electrodes facing each other are brought into contact at the position where the pressure is applied. Then, an external circuit detects the contact position and transmits the position data to a personal computer. Consequently, the position information is detected. In such tablet PC, the tablet is stacked on the liquid crystal display. For this reason, the liquid crystal display screen is provided at a deep position and thereby has a disadvantage of being hard to see, thick and heavy as compared with an ordinary display.

In order to improve the above disadvantage, there is disclosed a related art 1 (Japanese Patent Laid-Open No. 56-85792, patent family U.S. Pat. No. 4,345,248) in which a light receiving element is built in a substrate of a liquid crystal display device, and in which an input operation is performed by using an optical pen. FIG. 7 is a plan view of the liquid crystal display device in the related art 1. The liquid crystal display device is provided with a switching element “S” and a photosensitive element “P”. FIG. 8 shows a sectional view taken along the line 56 in the photosensitive element “P” shown in FIG. 7. The photosensitive element “P” is provided with n-type semiconductors 51, 53 and a p-type semiconductor 52 between the n-type semiconductors 51, 53 on a plane. However, in the photosensitive element “P” of the related art 1, a PNP-type semiconductor structure or an NPN-type semiconductor structure is arranged in a plane, as shown in FIG. 7, which thereby leads to a disadvantage that the area occupied by the elements is increased.

Thus, in relation to another structure of the light receiving element, there is known a manufacturing method of a vertical diode disclosed in a related art 2 (Japanese Patent Laid-Open No. 2-177375). FIG. 9 shows a sectional view of the light receiving element in the related art 2. As shown in FIG. 9, in the manufacturing method of the vertical diode, a lower electrode 62 is first formed on a substrate 61, and thereafter is plasma-treated in a gas containing phosphorus. Then, on the plasma-treated surface, semiconductor layers 63 (63n, 63i, 63p) are stacked in turn, so as to form a three-layer structure of N-I-P. Next, the surface of the semiconductor layer 63 is plasma-treated in a gas containing boron, and thereafter an upper electrode 64 is formed. It is noted that the dopant used in each of the plasma-treatments is a same conductivity type dopant as that of each semiconductor layer. Specifically, the surface of the lower electrode 62 on the side in contact with the N-type semiconductor layer 63n is plasma-treated under an atmosphere containing an N-type dopant. On the other hand, the surface of the P-type semiconductor layer 63p is plasma-treated under an atmosphere containing a P-type dopant. In this way, the dopant is selected so as to improve the ohmic contact between the semiconductor layer and the metallic electrode. When such vertical diode is built onto the substrate of the liquid crystal display device as described in the related art 1, there arises a disadvantage that processes added at the time of manufacture increase, and thereby the manufacturing processes become complicated. That is, it is necessary to continually form the N-I-P semiconductor layers at the time of manufacturing the vertical diode, and hence, processes such as a depositing process, a photoresist process, an etching process, a resist removing process are needed in addition to forming processes of the semiconductor layer in the liquid crystal display device. Therefore, there arise a disadvantage that processes added at the time of manufacture increase, and thereby the manufacturing processes become complicated.

### SUMMARY OF THE INVENTION

In view of the foregoing and other exemplary problems, drawbacks, and disadvantages of the related art methods and structures, exemplary feature of the present invention is to provide a vertical diode, a matrix position sensitive apparatus, which can be easily manufactured, and a manufacturing method of the same.

A vertical diode according to the present invention, formed by stacking semiconductor layers, includes (1) a lower electrode whose surface is plasma-treated in a gas containing an element which becomes a P-type or N-type conductivity type, and (2) a non-doped semiconductor layer provided on the lower electrode. The P-type or N-type semiconductor area is formed in a contact surface of the non-doped semiconductor layer in contact with the plasma-treated surface of the lower electrode.

A matrix position sensitive apparatus according to the present invention includes a substrate and the above-mentioned vertical diodes which are arranged on the substrate in a matrix form.

A manufacturing method of a vertical diode according to the present invention, formed by stacking semiconductor layers, includes (1) plasma-treating the surface of a lower electrode in a gas containing an element which becomes a P-type or N-type conductivity type, (2) forming a non-doped semiconductor layer on the lower electrode, and (3) forming a contact surface of the non-doped semiconductor layer in contact with the plasma-treated surface of the lower electrode, into a P-type or N-type semiconductor area.

A manufacturing method of a matrix position sensitive apparatus according to the present invention includes (1) forming the above-mentioned vertical diodes on a substrate in a matrix form, (2) forming the thin-film transistors according to claim 9 on the substrate in the matrix form, and (3) forming pixel areas controlled by the thin-film transistors on the substrate in the matrix form.

As described above, the vertical diode, the matrix position sensitive apparatus, and the manufacturing method of the same, according to the present invention, have an effect that the vertical diode and the matrix position sensitive apparatus can be easily manufactured.

### BRIEF DESCRIPTION OF THE DRAWINGS

The exemplary aspects, features and advantages of the present invention will become more apparent from the following detailed description when taken in conjunction with the accompanying drawings wherein:

FIG. 1 is a plan view showing a layout of a matrix position sensitive apparatus according to a first embodiment of the present invention;

FIG. 2 is a sectional view taken along line I-I and line II-II of the matrix position sensitive apparatus shown in FIG. 1;

FIG. 3A is a sectional view showing manufacturing process 1 of the matrix position sensitive apparatus shown in FIG. 2;

FIG. 3B is a sectional view showing manufacturing process 2 of the matrix position sensitive apparatus shown in FIG. 2;

FIG. 3C is a sectional view showing manufacturing process 3 of the matrix position sensitive apparatus shown in FIG. 2;

FIG. 3D is a sectional view showing manufacturing process 4 of the matrix position sensitive apparatus shown in FIG. 2;

FIG. 4A is a sectional view showing a manufacturing process 5 of the matrix position sensitive apparatus shown in FIG. 2;

FIG. 4B is a sectional view showing a manufacturing process 6 of the matrix position sensitive apparatus shown in FIG. 2;

FIG. 4C is a sectional view showing a manufacturing process 7 of the matrix position sensitive apparatus shown in FIG. 2;

FIG. 4D is a sectional view showing a manufacturing process 8 of the matrix position sensitive apparatus shown in FIG. 2;

FIG. 5 is a plan view showing a layout of a matrix position sensitive apparatus according to a second embodiment of the present invention;

FIG. 6 is a sectional view taken along line III-III of the vertical diode shown in FIG. 5;

FIG. 7 is a plan view showing a liquid crystal display device in a related art 1;

FIG. 8 is a sectional view of a photosensitive element “P” in FIG. 7; and

FIG. 9 is a sectional view of a vertical diode in a related art 2.

### DETAILED DESCRIPTION OF THE EXEMPLARY ASPECTS

Exemplary aspects for carrying out the present invention will be described in detail below with reference to the drawing. The exemplary aspects described below show only illustrative examples in understanding the present invention, and the claims of the present invention are not limited to these exemplary aspects.

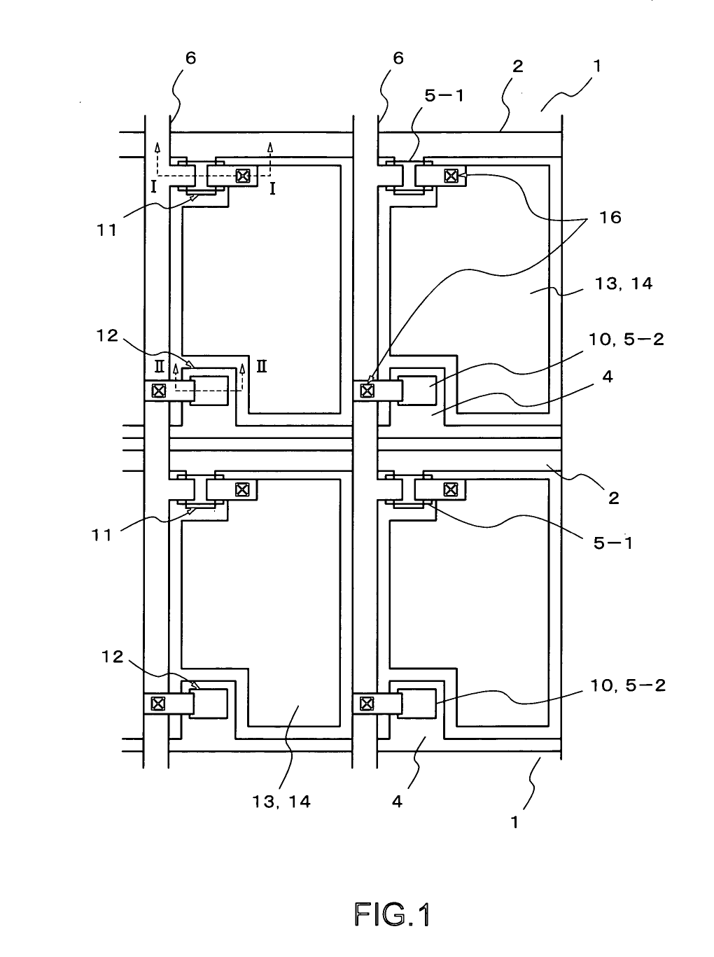

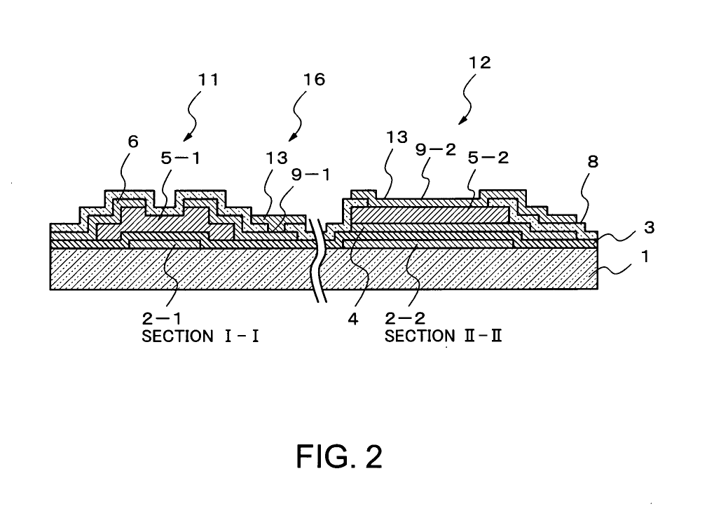

FIG. 1 is a plan view showing a layout of a matrix position sensitive apparatus according to a first embodiment of the present invention. FIG. 2 is a sectional view taken along line I-I in a thin film transistor (TFT) 11 and a contact 16, and taken along line II-II in a stacked photo diode 12, in FIG. 1. In the first embodiment according to the present invention, the TFT 11 and the stacked photo diode 12 are formed on a common substrate 1. It is noted that the TFT 11 is constituted to have an inverted staggered type structure.

In the photo diode 12, the upper surface of a lower electrode 4 shown in FIG. 2 is plasma-treated in a gas containing a dopant of an element by which a desired conductivity type is obtained. Thereby, the surface of the non-doped semiconductor layer provided on the lower electrode, (the lower surface of an island-like semiconductor layer 5-2), in contact with the plasma-treated surface, is formed into a semiconductor area of the desired conductivity type.

Normally, even when the surface of the non-doped semiconductor layer is plasma-treated in a gas containing a dopant, it is difficult to obtain an impurity doped semiconductor layer which can be practically used. However, when the lower electrode 4 is plasma-treated in a gas containing a dopant, and thereafter a non-doped semiconductor layer is formed by CVD (chemical vapor deposition)and the like, it is possible to obtain relatively easily an impurity doped semiconductor layer which can be practically used. This is based on the fact that when the electrode surface is plasma-treated in a gas containing a dopant, the electrode surface is made to be covered with the dopant, and that when anon-doped semiconductor layer is formed on the plasma-treated electrode surface, the dopant is taken into the non-doped semiconductor layer. In this way, the impurity doped semiconductor layer is selectively formed only in the place where the lower electrode 4 is present.

It is noted, the photo diode 12 is formed into a stacked type, and hence, an upper semiconductor layer in which an element with the conductivity type opposite to the conductivity type of the plasma-treated surface is doped, is formed on the non-doped semiconductor layer (island-like semiconductor layer 5-2). Then, an upper electrode 10 is formed on this upper semiconductor layer. It is noted that Indium Tin Oxide (ITO) and the like can be used for the upper electrode.

In the first embodiment according to the present invention, the matrix position sensitive apparatus is constituted by arranging TFTs 11, photo diodes 12 and pixel areas 13 forming a display surface, on the substrate 1 in a matrix form as shown in FIG. 1. The pixel area 13 is provided with a transparent electrode 14 on the surface thereof. The transparent electrode 14 includes, for example, ITO. The upper electrode 10 of the photo diode 12 also includes, for example, ITO. The TFT 11 is connected with the transparent electrode 14 used as the display surface via the contact 16. The photo diode 12 is formed as a vertical diode by providing the semiconductor layer 5-2 on the lower electrode 4, and by providing the upper electrode 10 on the semiconductor layer 5-2.

Next, a detailed constitution of the photo diode 12 and examples of each material and film thickness are explained below. In FIG. 2, a black mask (gate electrode) 2-2 is provided on the substrate 1 by patterning. The substrate 1 can be made of a glass or a plastic. The black mask 2-2 can be made of a Cr (chromium) film with a thickness of about 200 nm. A gate insulating film 3 is provided on the black mask 2-2. The gate insulating film 3 can be made of a silicon nitride (SiNx) film with a thickness of about 300 nm. The lower electrode 4 is provided at a position facing the black mask 2-2 via the gate insulating film 3. An oxide semiconductor and a compound semiconductor, such as ITO, SnO₂, ZnO, CuAlO₂, SrCu₂O₂, and also a stacked film made of these materials can be used as the lower electrode 4, in addition to a metal such as Cr and Mo (molybdenum). The surface of the lower electrode 4 is plasma-treated in a gas containing boron (for example, diborane B₂H₆) Then, the semiconductor layer 5-2 which is a non-doped semiconductor layer (non-doped hydrogenated amorphous silicon) is formed on this plasma-treated surface. At this time, the contact surface of the non-doped semiconductor layer (lower surface of the semiconductor layer 5-2), in contact with the plasma-treated surface, is formed into a P-type semiconductor area.

In this example, an N-type semiconductor layer included a non-doped hydrogenated amorphous silicon and a phosphorus doped N⁺ amorphous silicon is formed, so as to make the semiconductor layer 5-2 formed on the plasma-treated surface. A passivation film 8 made of an insulating material is formed on the semiconductor layer 5-2. A contact hole 9-2 is formed in the passivation film 8, and the upper electrode 10 is provided for the contact hole 9-2. In this way, the photo diode 12 is completed.

The semiconductor layer 5-2 is formed by making non-doped hydrogenated amorphous silicon in about 200 nm, and subsequently phosphorus doped hydrogenated amorphous silicon in about 50 nm deposited by CVD (Chemical Vapor Deposition). Then, the desired island-like semiconductor layer 5-2 is formed by a normal photoresist process and a normal reactive ion etching (RIE) process.

The non-doped amorphous silicon layer and the phosphorus doped N⁺ amorphous silicon layer can be formed on the plasma-treated surface of the lower electrode 4, only by adding two processes of a lower electrode forming process and a plasma-treatment process to the normal TFT process. In the first embodiment according to the present invention, a vertical diode used for a photo diode, a solar cell and the like can be built onto the TFT substrate by the sole addition of the two processes.

It is noted that as the photo diode 12, at least one of the lower electrode 4 and the upper electrode 10 needs to be a transparent electrode. When the transparent electrode is used for both the upper electrode 10 and the lower electrode 4, the black mask 2-2 needs to be formed in the underside of the lower electrode 4, as shown in FIG. 2. However, in the case where the lower electrode 4 is made of a light shielding material, the lower electrode 4 itself serves as the black mask, so that the black mask 2-2 can be eliminated. As an example of the light shielding material, there is a metal film made of Cr, Mo and the like.

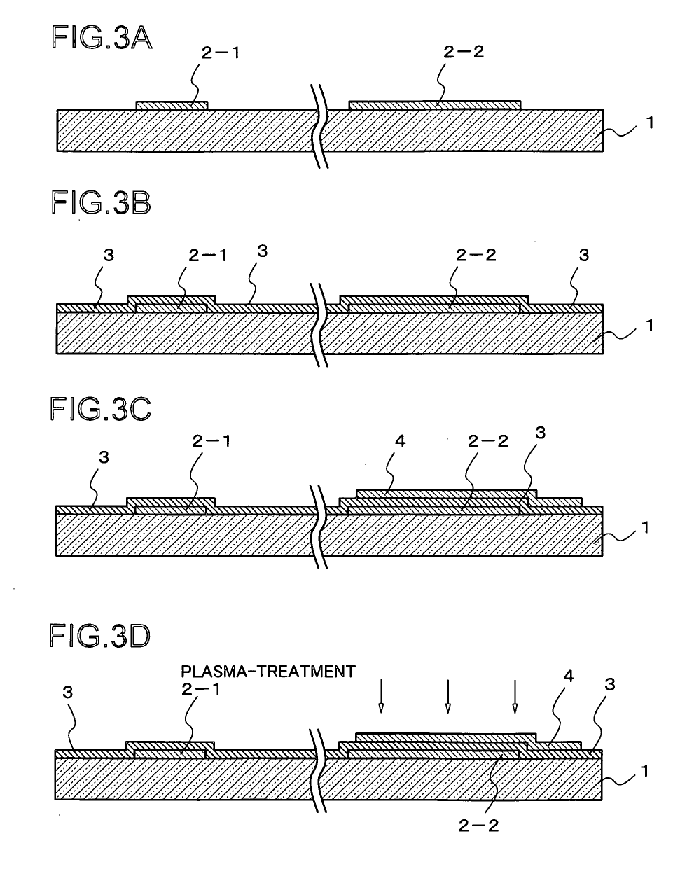

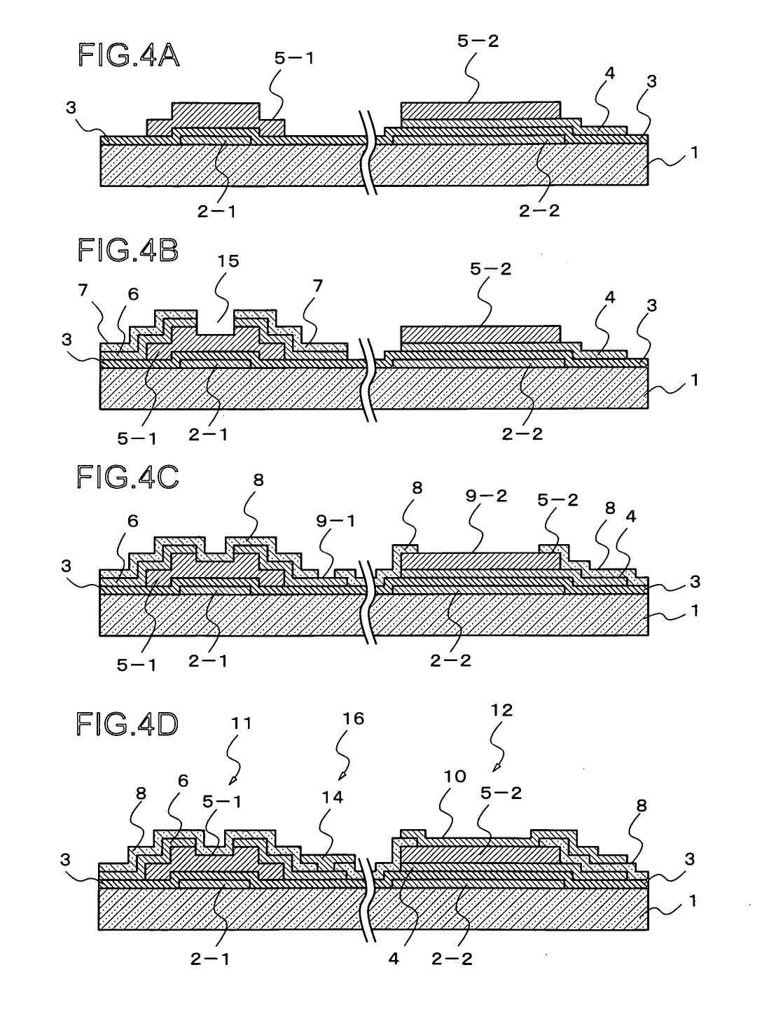

A manufacturing process of the matrix position sensitive apparatus including photo diodes and TFTs, which is the first embodiment according to the present invention, is explained in the following with reference to FIG. 3A to FIG. 3D and FIG. 4A to FIG. 4D. It is noted that in the manufacturing process 1 in FIG. 3A, there is shown an example in which the black mask 2-2 of the photo diode 12 is formed simultaneously with a gate electrode 2-1 of the TFT 11.

First, as shown in FIG. 3A, a film of a metal, for example Cr, serving as the gate electrode 2-l is formed in about 200 nm by sputtering, on the substrate 1 made of glass or plastic. The gate electrode 2-1 made of the metal serves as the black mask 2-2 on the side of the photo diode 12. After the gate electrode 2-1 and the black mask 2-2 are formed by sputtering, the resist of unnecessary parts is selectively removed by the normal photoresist process. Then, the Cr film of the part where the resist is removed is etched by, for example, a cerium nitrate-based etching liquid. Thereby, the Cr film in the part of the gate electrode 2-1 and the black mask 2-2 are protected by the resist, so as to be left. Thereafter, the gate electrode 2-1 and the black mask 2-2 are formed by removing the resist.

Next, as shown in FIG. 3B, a nitride film with a thickness of about 300 nm serving as the gate insulating film 3 is formed by CVD. The gate insulating film 3 may also be formed by stacking such as a oxide film with a thickness of about 100 nm and a nitride film with a thickness of about 200 nm. By combining plural films in this way, it is possible to adjust the transmittance of the gate insulating film 3 and to prevent a pinhole from being formed.

Next, as shown in FIG. 3C, for example, a Cr film with a thickness of about 100 nm is formed by sputtering and then formed into the lower electrode 4 of the photo diode 12 through the photoresist process, the etching process and the resist removing process. As the lower electrode 4, it is possible to use an oxide semiconductor and a compound semiconductor, such as ITO, SnO₂, ZnO, CuAlO₂, SrCu₂O₂, and further a stacked film of these materials, in addition to a metal such as Cr, Mo. It is noted that a transparent electrode normally has a larger resistance than a metallic electrode. Thus, the transparent electrode is generally used on the incident light side. However, as in the present embodiment, when the surface of the lower electrode 4 is plasma-treated, the junction by using the transparent electrode can be more easily made than that of the metallic electrode. Therefore, ITO, SnO₂, and a combination thereof are more suitable for the lower electrode 4.

It is noted, when the light shielding performance is required for the lower electrode 4 in the photo diode 12, a metal film made of such as Cr, Mo, which has a thickness necessary for the light shielding, is selected as the lower electrode 4. In this way, when the lower electrode 4 is made of a metal, the lower electrode also serves as the light shield, so that the black mask 2-2 can be eliminated.

Next, as shown in FIG. 3D, when obtaining a P-type semiconductor layer on the lower electrode 4, the entire surface of the substrate 1 is plasma-treated in a gas containing a boron (for example, diborane B₂H₆). On the other hand, when obtaining an N-type semiconductor layer on the lower electrode 4, the entire surface of the substrate 1 is plasma-treated in a gas containing a phosphorus (for example, phosphine PH₃) The plasma-treatment is performed after the patterning of the lower electrode 4, but may also be performed before the patterning and after the layer of the lower electrode 4 is formed.

Next, as shown in FIG. 4A, non-doped hydrogenated amorphous silicon is deposited in a thickness of about 200 nm by CVD, and subsequently phosphorus doped hydrogenated amorphous silicon is deposited in a thickness of about 50 nm by CVD. Then, island-like semiconductor layers 5-1, 5-2 are formed by the normal photoresist process and the normal RIE process. The semiconductor layers 5-1, 5-2 can also be similarly formed by microcrystalline silicon and polycrystalline silicon, in addition to the above described hydrogenated amorphous silicon.

Subsequently, as shown in FIG. 4B, a Cr film with a thickness of about 140 nm is formed as a drain electrode 6 by sputtering. A photoresist 7 is applied in a thickness of about 2 μm on this film, and it is exposed and developed. As the photomask (not shown) used here, it is preferred to use a halftone mask which is formed as a transparent film in a part corresponding to a channel region 15 of the TFT 11, which is formed as a black mask in a part corresponding to the drain electrode 6 of the TFT 11, and which is formed as a semi-transparent film in other parts. The semi-transparent film of the halftone mask preferably has a transmittance of about 40%. It is noted, without using the halftone mask as the photomask, the resist with thicknesses of three levels can be obtained even on a fine pattern which can not be resolved by an exposure machine.

By using the photomask as described above, the resist of the region of the channel region 15 is removed, the resist of the region of the drain electrode 6 remains thickly, and the resist of other regions remains thin. In this state, Cr of the channel region 15 is etched by a cerium nitrate-based etching liquid. Thereafter, an N⁺ layer of the channel region 15 is dry-etched by an SF₆-based gas so that a channel etching region is formed in the channel region 15. Then, the thin resist corresponding to the semi-transparent film of the halftone mask is removed by ashing or re-developing the resist. Thereby, Cr in the region under the thin resist is removed. Thus, the Cr in the region corresponding to the drain electrode, where the resist remains, is left so that the drain electrode 6 is formed (the state shown in FIG. 4B).

Next, after the resist 7 is removed, as shown in FIG. 4C, the passivation film 8 is deposited in a thickness of about 150 nm by CVD. A nitride film and the like are used as the passivation film 8. Contact holes 9-1, 9-2 are formed in the passivation film 8 by a normal photolithographic process and a normal etching process using a hydrofluoric acid-based etching liquid.

Finally, as shown in FIG. 4D, the transparent electrode 14 of the pixel area 13 and the upper electrode 10 of the photo diode 12 are formed in a thickness of about 50 nm by sputtering. ITO and the, like are used for the transparent electrode 14 and the upper electrode 10. Subsequently, the other resists are removed by a normal photoresist process and a normal etching process using an aqua regia-based etching liquid. Thus, the matrix position sensitive apparatus in which the TFTs 11 and the photo diodes 12 are formed, is completed.

The first embodiment according to the present invention can be applied to a tablet PC using a light pen and the like by displaying by the TFT 11 and sampling the position of the light pen by the photo diode 12.

As described above, in the first embodiment, the lower electrode 4 is plasma-treated and then the non-doped semiconductor layer is formed on it, and thereby the doped semiconductor layer can be formed. Accordingly, the first embodiment has an effect that a desired conductivity type semiconductor layer can be easily formed at the lower part of the non-doped semiconductor layer. Further, the first embodiment has an effect that the desired conductivity type semiconductor layer can be easily formed only by adding a lower electrode forming process and a plasma-treatment process to a normal TFT process. Therefore, the first embodiment has an effect that a vertical diode can be easily manufactured together with a liquid crystal display device (TFT).

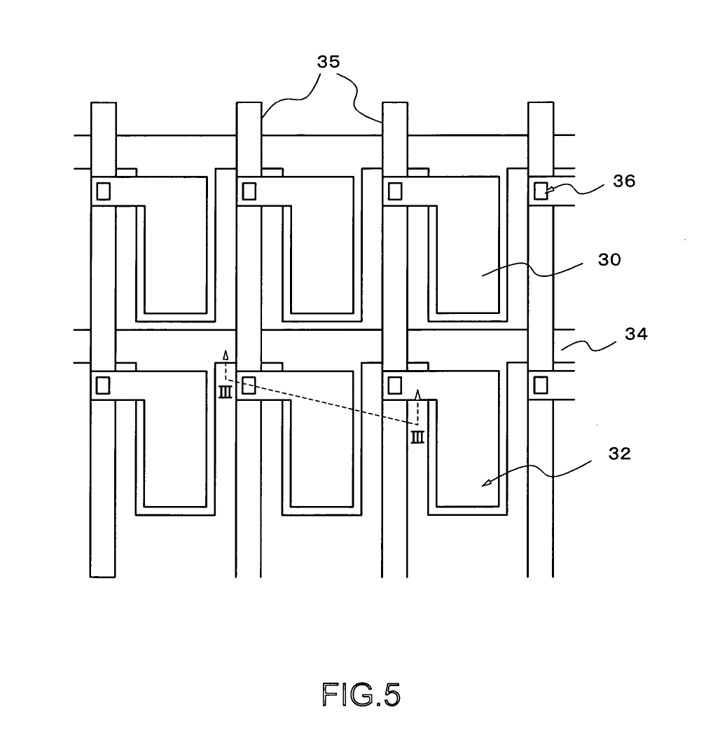

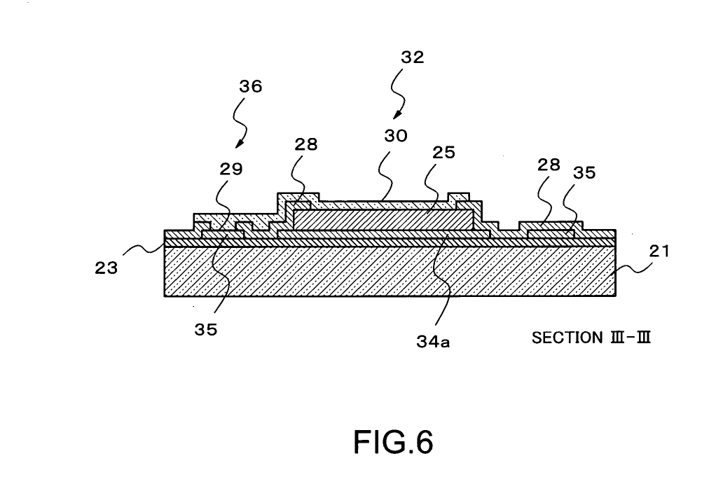

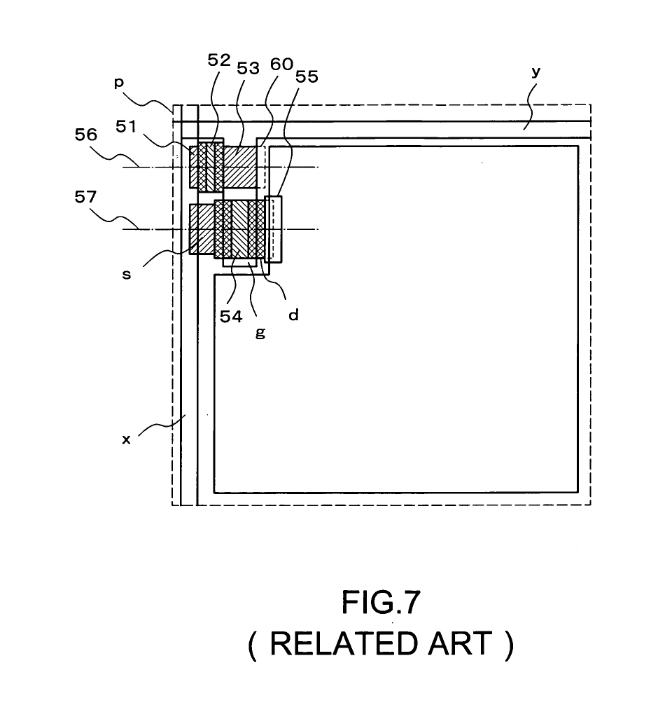

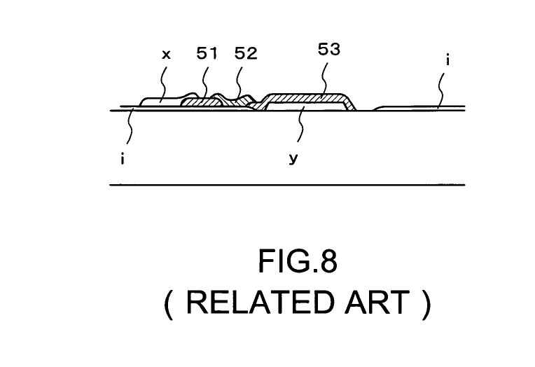

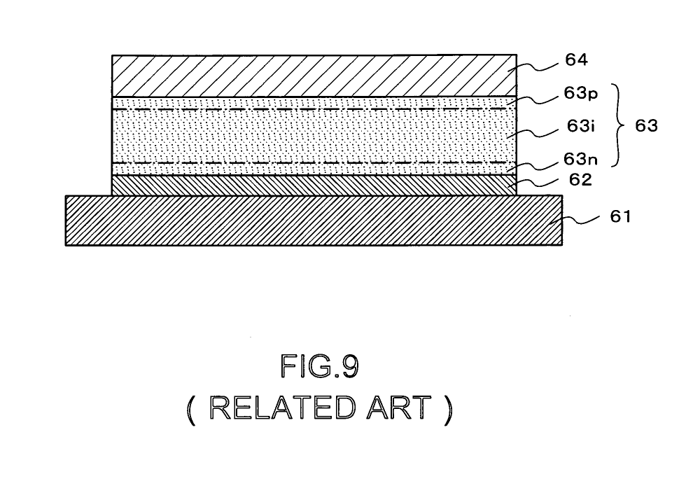

FIG. 5 is a plan view showing a layout of a matrix position sensitive apparatus according to a second embodiment of the present invention. FIG. 6 is a sectional view taken along line III-III in FIG. 5. As shown in FIG. 5, the second embodiment according to the present invention is constituted by arranging photo diodes 32 in a matrix form on a plane. In this embodiment, the characteristics (for example, open-circuit voltage and short-circuit current) of the photo diode 32 can be read by using a scanning line 34 and a data line 35. A lower electrode 34a of the photo diode 32 is connected with the scanning line 34. An upper electrode 30 of the photo diode 32 is connected with the data line 35 via a contact 36.

A manufacturing method of the second embodiment is described below. After a protective film 23 is formed (may not be formed) on a substrate 21, the scanning line 34 is patterned and formed (together with the lower electrode 34a) Then, the surface of the lower electrode 34a formed together with the scanning line 34 is plasma-treated in a gas containing boron (for example, diborane: B₂H₆). On the plasma-treated surface of the lower electrode 34a, an island-like semiconductor layer 25 made of non-doped hydrogenated amorphous silicon and phosphorus doped hydrogenated amorphous silicon is continuously formed by CVD. Subsequently, the semiconductor layer 25 is patterned, so that the shape of the semiconductor layer 25 is completed. Consequently, the lower surface of semiconductor layer 25 in contact with the plasma-treated surface is formed into a desired conductivity type semiconductor region. In this way, it is possible to relatively easily obtain an impurity doped semiconductor layer which can be practically used. On the semiconductor layer 25, there is formed an upper semiconductor layer doped with an element which becomes a conductivity type opposite to the conductivity type of the plasma-treated surface. Next, after the data line 35 is formed, a passivation film (insulating film) 28 is formed on the semiconductor layer 25 and the data line 35. Then, contact holes 29-1, 29-2 are opened on the island-like semiconductor layer 25 and in the passivation film (insulating film) 28 in the part of the contact 36. The upper electrode 30 is formed in the part of the semiconductor layer 25 and the contact 36. The upper electrode 30 can be formed into a desired shape by patterning. It is noted that the passivation film and the contact hole can be further added depending on requirements.

It is noted that means (CVD, RIE and the like) for forming each film, materials (Ct, ITO and the like), and the film thickness can be applied under the same condition as the first embodiment. As an example, an oxide semiconductor and a compound semiconductor, such as ITO, SnO₂, ZnO, CuAlO₂, SrCu₂O₂, and further a stacked film of these materials, can be used for the lower electrode 34a, in addition to a metal such as Cr, Mo. However, on the surface of the lower electrode 34a, the junction by using the transparent electrode can be more easily made than that of the metallic electrode. Thus, ITO, SnO₂ and a combination thereof are more suitable for the lower electrode 34a.

When obtaining P-type semiconductor layer on the lower electrode 34a as in the first embodiment, the substrate 21 is plasma-treated in a gas containing boron (for example, diborane B₂H₆). On the other hand, when obtaining an N-type semiconductor layer on the lower electrode 34a, the substrate 21 is plasma-treated in a gas containing phosphorus (for example, phosphine PH₃).

Further, the semiconductor layer 25 is formed by making non-doped hydrogenated amorphous silicon and subsequently phosphorus doped hydrogenated amorphous silicon deposited by CVD. However, the semiconductor layer 25 can be similarly formed by microcrystalline silicon and polycrystalline silicon, in addition to the hydrogenated amorphous silicon.

The present embodiment can be applied to an X-ray two-dimensional image sensor, a tablet using a light pen and the like, by sampling the characteristic corresponding to the position of the scanning line 34 and the data line 35.

As described above, in the second embodiment, the lower electrode 34a is plasma-treated and then the non-doped semiconductor layer is formed on it, and thereby the doped semiconductor layer can be formed. Therefore, the second embodiment has an effect that a desired conductivity type semiconductor layer can be easily formed at the lower part of the non-doped semiconductor layer.

In the photo diode 12 or 32 described in the first embodiment or the second embodiment, it goes without saying that plural photo diodes, which are arrange in different, positions, are connected with each other to increase the electromotive force, by using the lower electrode 14 or 34a, the upper electrode 10 or 30, the contact 16 or 36, and the like.

Further, in each of the above described embodiments, the vertical diode is formed as P-I-N type from the bottom, but it goes without saying that the vertical diode can be reversely formed as N-I-P type. In this case, the TFT is formed into a P-channel type.

As an utilization example of the present invention, the present invention can be applied to a tablet PC, a liquid crystal display which have a tablet function, a two-dimensional X ray sensor, and the like.

While this invention has been described in connection with certain exemplary embodiments, it is to be understood that the subject matter encompassed by way of this invention is not to be limited to those specific embodiments. On the contrary, it is intended for the subject matter of the invention to include all alternatives, modifications and equivalents as can be included within the spirit and scope of the following claims.

Further, the inventor's intent is to retain all equivalents of the claimed invention and all claim elements even if the claims are amended later during prosecution.

1. A vertical diode formed by stacking semiconductor layers, comprising:
a lower electrode whose surface is plasma-treated in a gas containing an element which becomes a P-type or N-type conductivity type; and
a non-doped semiconductor layer provided on the lower electrode, wherein the P-type or N-type semiconductor area is formed in a contact surface of the non-doped semiconductor layer in contact with the plasma-treated surface of the lower electrode.

2. The vertical diode according to claim 1, further comprising:
an upper semiconductor layer, doped with an element which becomes a conductivity type opposite to the conductivity type, formed on the non-doped semiconductor layer; and
an upper electrode formed on the upper semiconductor layer.

3. The vertical diode according to claim 1,
wherein the lower electrode is formed by one of a metallic film, an oxide semiconductor film, a compound semiconductor film and a film formed by stacking these films.

4. The vertical diode according to claim 1,
wherein one of the lower electrode and the upper electrode is a transparent electrode.

5. The vertical diode according to claim 4, further comprising a black mask in the underside of the lower electrode.

6. The vertical diode according to claim 1, wherein the non-doped semiconductor layer comprises one of hydrogenated amorphous silicon, microcrystalline silicon and polycrystalline silicon.

7. A matrix position sensitive apparatus comprising:
a substrate and
the vertical diodes according to claim 1 which are arranged on the substrate in a matrix form.

8. The matrix position sensitive apparatus according to claim 7, further comprising:
plural data lines arranged in parallel with each other; and
plural scanning lines arranged orthogonal to the data lines and parallel with each other.

9. The matrix position sensitive apparatus according to claim 7, further comprising:
thin-film transistors arranged on the substrate in a matrix form; and
pixel areas arranged on the substrate in the matrix form and controlled by the thin-film transistors.

10. The matrix position sensitive apparatus according to claim 9,
wherein the thin-film transistor comprises a gate electrode, an insulating film, a semiconductor layer and a drain electrode on the substrate.

11. The matrix position sensitive apparatus according to claim 10,
wherein the gate electrode of the thin-film transistor and a black mask of the vertical diode,
the insulating film of the thin-film transistor and an insulating film of the vertical diode, and
the semiconductor layer of the thin-film transistor and a non-doped semiconductor layer of the vertical diode, are formed of a same material in respective pairs.

12. The matrix position sensitive apparatus according to claim 9, further comprising:
plural drain electrodes which supply current to the thin-film transistors; and plural gate electrodes which control the supply of current to the thin-film transistors.

13. The matrix position sensitive apparatus according to claim 7,
wherein tablet detection is performed by the vertical diodes and a light pen.

14. The matrix position sensitive apparatus according to claim 9,
wherein tablet detection is performed by the vertical diodes and the light pen, and wherein liquid crystal display is performed by the thin-film transistors and the pixel areas.

15. A manufacturing method of a vertical diode formed by stacking semiconductor layers, comprising:
plasma-treating the surface of a lower electrode in a gas containing an element which becomes a P-type or N-type conductivity type;
forming a non-doped semiconductor layer on the lower electrode; and
forming a contact surface of the non-doped semiconductor layer in contact with the plasma-treated surface of the lower electrode, into a P-type or N-type semiconductor area.

16. The manufacturing method of the vertical diode according to claim 15, further comprising:
forming an upper semiconductor layer doped with an element which becomes a conductivity type opposite to the conductivity type on the non-doped semiconductor layer; and
forming an upper electrode on the upper semiconductor layer.

17. The manufacturing method of the vertical diode according to claim 16, wherein one of the lower electrode and the upper electrode is a transparent electrode.

18. A manufacturing method of a matrix position sensitive apparatus, comprising:
forming vertical diodes on a substrate in a matrix form, said vertical diodes each comprising:
a lower electrode whose surface is plasma-treated in a gas containing an element which becomes a P-type or N-type conductivity type; and
a non-doped semiconductor layer provided on the lower electrode,
wherein the P-type or N-type semiconductor area is formed in a contact surface of the non-doped semiconductor layer in contact with the plasma-treated surface of the lower electrode;
forming the thin-film transistors according to claim 9 on the substrate in a matrix form; and
forming pixel areas controlled by the thin-film transistors on the substrate in a matrix form.

19. The manufacturing method of the matrix position sensitive apparatus according to claim 18, wherein
an insulating film of the thin-film transistors and an insulating film of the vertical diodes, and
a semiconductor layer of the thin-film transistors and a non-doped semiconductor layer of the vertical diodes, are formed by a same manufacturing process in respective pairs.

20. The manufacturing method of the matrix position sensitive apparatus according to claim 18,
wherein a gate electrode of the thin-film transistors and a black mask of the vertical diodes are formed by a same manufacturing process.
